(19) United States
(12) Patent Application Publication
(10) Pub. No.: US 2006/0119392 A1
(43) Pub. Date: Jun. 8, 2006

(54) Semiconductor integrated circuit and layout design method thereof, and standard cell

(75) Inventors: Mitsushi Nozoe, Osaka (JP); Junichi Yano, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/285,020

(22) Filed: Nov. 23, 2005

(30) Foreign Application Priority Data
Dec. 2, 2004 (JP) 2004-350343

(51) Int. Cl. H03K 19/00

(52) U.S. Cl. 326/101

(57) ABSTRACT

A semiconductor integrated circuit comprises: a first standard cell which includes a first logic circuit and a first switch for controlling current supply to the first logic circuit; and a second standard cell which includes a second logic circuit and a second switch for controlling current supply to the second logic circuit. The first switch is shared with the second standard cell as the second switch.

### BACKGROUND OF THE INVENTION

The present invention relates to a semiconductor integrated circuit which is designed based on a standard cell scheme and a layout design method thereof.

In recent years, semiconductor integrated circuits for multimedia applications have been demanded to achieve high speed operation and low power consumption. They have also been demanded to achieve a small circuit area.

For example, a high speed operation of a semiconductor integrated circuit is achieved by lowering the threshold voltage of transistors. The on-current of the transistors increases as the threshold voltage is lowered, whereby a larger load can be driven. As a result, each transistor and the semiconductor integrated circuit operate with high speed.

However, a low threshold voltage causes an increase in leakage current, which impedes the reduction of power consumption. One example of reducing the leakage current is a circuit contraption for dynamically increasing the threshold voltage when a high speed operation is not necessary such that the leakage current is reduced. Another example is cutting off the power supply to transistors when a circuit is not used. However, the power supply to a device which operates intermittently or to a memory device, such as a register, which must hold its content, cannot be cut off.

For example, a switch for cutting off the leakage current is provided to each standard cell, such as a NAND circuit. Specifically, a switch transistor of a high threshold voltage is inserted in series with transistors of general logic circuits. With this structure, it can be selectively controlled for each standard cell whether or not to cut off the leakage current while the power is supplied to a semiconductor integrated circuit. Therefore, the power consumption can be effectively reduced (see, for example, “Riiku Denryu to Tatakau [Fight against leakage current]”, Nikkei Electronics, Nikkei Business Publications, Inc., Apr. 26, 2004, Vol. 872, pp. 110-119).

According to a standard cell scheme for designing a semiconductor integrated circuit, standard cells are placed over a semiconductor substrate, and wirings are routed among the standard cells according to the specifications of the semiconductor integrated circuit. With this scheme, various circuits having different functions can be designed within a short period of time.

A standard cell having a switch is described with an example of a 2-input NAND cell. FIG. 3 is a gate level circuit diagram of the 2-input NAND cell having a switch. FIG. 4 is a transistor level circuit diagram of the 2-input NAND cell of FIG. 3. A 2-input NAND gate 12 is formed by transistors with low threshold voltage (Vt), and a switch transistor 13 is formed by a transistor with high threshold voltage (Vt).

The switch transistor 13 is an NMOS transistor to which an inverted sleep signal NSL is input. When the inverted sleep signal NSL is at low level, the switch transistor 13 is off. Accordingly, the current path from the 2-input NAND gate 12 to power supply VSS is cut off, whereby the leakage current is cut off. Thus, the standard cell of FIG. 3 is controlled by the inverted sleep signal NSL as to whether or not the leakage current is cut off.

FIG. 8 is a cell layout showing an example of a conventional structure of the 2-input NAND cell of FIG. 3. This cell is a standard cell of the 2-input NAND cell of the circuit of FIG. 3. When at least one switch is added to each standard cell for power reduction as shown in FIG. 8, the area of each standard cell increases as each standard cell has at least one additional transistor. A semiconductor integrated circuit designed based on a standard cell scheme has a plurality of rows, each of which includes a plurality of standard cells. Adjacent two standard cells may have some circuit sections which can be shared. By sharing such circuit sections, the standard cell rows are shortened, reducing the area of the semiconductor integrated circuit.

For example, if source regions of the same potential adjoin each other between adjacent standard cells, the source regions (including a source diffusion layer and contact vias provided thereon) can be shared (see, for example, Japanese Laid-Open Patent Publications Nos. 5-41452 and 2001-94054). In this case, the length in the column direction (width) of the semiconductor integrated circuit can be shortened, reducing its area.

FIG. 9 is a layout of a semiconductor integrated circuit including two standard cells of FIG. 8 where a source region is shared between adjacent standard cells. The two transistors 980 sharing their source regions are equivalent to two units of the switch transistor 930 of FIG. 8. Thus, the width (length in the column direction) of the semiconductor integrated circuit is shortened, reducing its area, as compared with a case where two standard cells of FIG. 8 are abutted side by side.

However, the semiconductor integrated circuit of FIG. 9 still has a large circuit area as compared with a circuit including no switch transistor. In the semiconductor integrated circuit of FIG. 9, the switch transistors 980 sharing their source regions have two gate electrodes and two input pins 985 for the inverted sleep signal NSL. In the routing process which uses an automatic layout tool, if the number of pins for inputs/outputs is large, the routing process become complicated. As a result, the wirings of the layout congest, making it difficult to reduce the circuit area.

### SUMMARY OF THE INVENTION

An objective of the present invention is to reduce the area of a semiconductor integrated circuit designed based on a standard cell scheme.

Specifically, according to an aspect of the present invention, there is provided a semiconductor integrated circuit, comprising: a first standard cell which includes a first logic circuit and a first switch for controlling current supply to the first logic circuit; and a second standard cell which includes a second logic circuit and a second switch for controlling current supply to the second logic circuit, wherein the first switch is shared with the second standard cell as the second switch.

In the above-described semiconductor integrated circuit, the first switch is shared between the first and second standard cells, and therefore, the area of the semiconductor integrated circuit is small as compared with a circuit in which the first switch is not shared.

Preferably, in the above-described semiconductor integrated circuit, the first switch exists on a side which is closer to the second logic circuit.

Preferably, in the above-described semiconductor integrated circuit, the first switch is a transistor.

Preferably, the gate width of the transistor which constitutes the first switch is greater than those of the other transistors included in the first and second standard cells.

Preferably, a source region of the transistor which constitutes the first switch is shared with a transistor which functions as the second switch.

Preferably, a gate electrode of the transistor which constitutes the first switch is shared with a transistor which functions as the second switch.

Preferably, a gate electrode of the transistor which constitutes the first switch includes a straight portion which is elongated in a direction perpendicular to a boundary line between the first standard cell and the second standard cell.

Preferably, a drain region of the transistor which constitutes the first switch is shared with a transistor which functions as the second switch.

Preferably, a threshold voltage of the transistor which constitutes the first switch is higher than those of the other transistors included in the first and second standard cells.

With the above features, the leakage currents in the first and second logic circuit can be reduced.

According to another aspect of the present invention, there is provided a semiconductor integrated circuit, comprising: a first standard cell which includes a first logic circuit and a first transistor for controlling current supply to the first logic circuit; and a second standard cell which includes a second logic circuit and a second transistor for controlling current supply to the second logic circuit, wherein a source region of the first transistor is shared with the second standard cell as a source region of the second transistor, and a gate electrode of the first transistor is shared with the second standard cell as a gate electrode of the second transistor.

In the above-described semiconductor integrated circuit, the source region and the gate electrode of the first transistor are shared between the first and second standard cells, and therefore, the area of the semiconductor integrated circuit is small as compared with a circuit in which these elements are not shared.

Preferably, in the above-described semiconductor integrated circuit, a gate electrode of the first transistor includes a straight portion which is elongated in a direction perpendicular to a boundary line between the first standard cell and the second standard cell.

With the above feature, the source region, gate electrode, and drain region of the first transistor are in the vicinity of the boundary line of the standard cells. Thus, sharing of a transistor between two standard cells is easily achieved.

Preferably, in the above-described semiconductor integrated circuit, a threshold voltage of the first transistor is higher than those of the other transistors included in the first and second standard cells.

With the above feature, the leakage currents in the first and second logic circuit can be reduced.

According to still another aspect of the present invention, there is provided a standard cell, comprising: a logic circuit; and a control transistor for controlling current supply to the logic circuit, wherein a gate electrode of the control transistor includes a straight portion which is elongated in a direction perpendicular to gate electrodes of transistors which constitute the logic circuit.

Preferably, in the above-described standard cell, the gate electrode of the control transistor includes only the straight portion which is elongated in a direction perpendicular to the gate electrodes of the transistors which constitute the logic circuit.

According to still another aspect of the present invention, there is provided a method for designing a layout of a semiconductor integrated circuit, comprising the steps of: placing a first standard cell which includes a first logic circuit and a first switch for controlling current supply to the first logic circuit and a second standard cell which includes a second logic circuit and a second switch for controlling current supply to the second logic circuit such that the first switch is shared with the second standard cell as the second switch while no pin is provided in a shared portion of the first and second standard cells; and providing only one pin in the shared portion.

With the above feature, the number of pins of the semiconductor integrated circuit can be reduced, whereby the circuit area can be reduced accordingly.

According to still another aspect of the present invention, there is provided a method for designing a layout of a semiconductor integrated circuit, comprising the steps of: placing a first standard cell which includes a first logic circuit and a first switch for controlling current supply to the first logic circuit and a second standard cell which includes a second logic circuit and a second switch for controlling current supply to the second logic circuit such that the first switch is shared with the second standard cell as the second switch while pins are provided in a shared portion of the first and second standard cells; and deleting one of the pins provided in the shared portion.

According to still another aspect of the present invention, there is provided a method for designing a layout of a semiconductor integrated circuit, comprising the steps of: placing a first standard cell which includes a first logic circuit and a first transistor for controlling current supply to the first logic circuit and a second standard cell which includes a second logic circuit and a second transistor for controlling current supply to the second logic circuit such that a source region of the first transistor is shared with the second standard cell as a source region of the second transistor, and a gate electrode of the first transistor is shared with the second standard cell as a gate electrode of the second transistor, while no pin is provided in a shared portion of the first and second standard cells; and providing only one pin in the shared portion.

According to still another aspect of the present invention, there is provided a method for designing a layout of a semiconductor integrated circuit, comprising the steps of: placing a first standard cell which includes a first logic circuit and a first transistor for controlling current supply to the first logic circuit and a second standard cell which includes a second logic circuit and a second transistor for controlling current supply to the second logic circuit such that a source region of the first transistor is shared with the second standard cell as a source region of the second transistor, and a gate electrode of the first transistor is shared with the second standard cell as a gate electrode of the second transistor, while pins are provided in a shared portion of the first and second standard cells; and deleting one of the pins provided in the shared portion.

Preferably, the above-described layout design method further comprises the step of selecting one of a delay library having a delay value which is to be caused when a switch or transistor is shared between the first and second standard cells and a delay library having a delay value which is to be caused when a switch or transistor is not shared between the first and second standard cells to perform a delay calculation using the selected delay library.

Preferably, in the above-described layout design method, the step of placing the standard cells includes replacing, if the first and second standard cells are placed side by side, the first and second standard cells with a complex cell using a layout library which includes layout data of the first and second standard cells and layout data of the complex cell, the complex cell being constructed by consolidating the first and second standard cells by sharing the switch or transistor therebetween.

As described above, according to the present invention, not only the source region of a switch transistor but also a gate electrode, etc., of the switch transistor are shared between standard cells. Therefore, the area of a semiconductor integrated circuit can be reduced. By reducing the number of input pins of the switch transistor, the wiring resources are increased, and the routing congestion is reduced. As a result, the circuit area can be reduced.

### BRIEF DESCRIPTION OF THE DRAWINGS

FIG. 1 is a layout of a semiconductor integrated circuit according to embodiment 1 of the present invention.

FIG. 2 is a gate level circuit diagram of the semiconductor integrated circuit of FIG. 1.

FIG. 3 is a gate level circuit diagram of a 2-input NAND cell having a switch.

FIG. 4 is a transistor level circuit diagram of the 2-input NAND cell of FIG. 3.

FIG. 5 is a cell layout showing an example of the structure of the 2-input NAND cell of FIG. 3.

FIG. 6 is a layout of a semiconductor integrated circuit according to embodiment 2 of the present invention.

FIG. 7 is a cell layout showing another example of the structure of the 2 input NAND cell of FIG. 3.

FIG. 8 is a cell layout showing an example of a conventional structure of the 2-input NAND cell of FIG. 3.

FIG. 9 is a layout of a semiconductor integrated circuit including two standard cells of FIG. 8 where a source region is shared between adjacent standard cells.

### DESCRIPTION OF THE PREFERRED EMBODIMENTS

Hereinafter, embodiments of the present invention will be described with reference to the drawings.

### EMBODIMENT 1

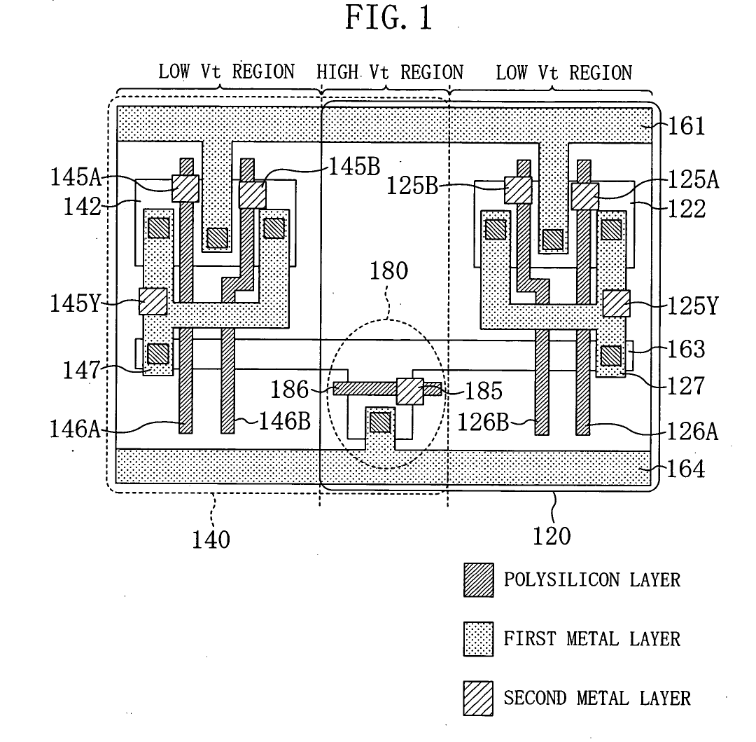

FIG. 1 is a layout of a semiconductor integrated circuit according to embodiment 1 of the present invention. The semiconductor integrated circuit of FIG. 1 includes a first standard cell 120 and a second standard cell 140. Part of the first standard cell 120 is shared with the second standard cell 140. Hereinafter, a standard cell including 2-input NAND gate, such as the first and second standard cells 120 and 140, is described as an example. However, the following descriptions are also applicable to a standard cell which includes a logic circuit of a different type.

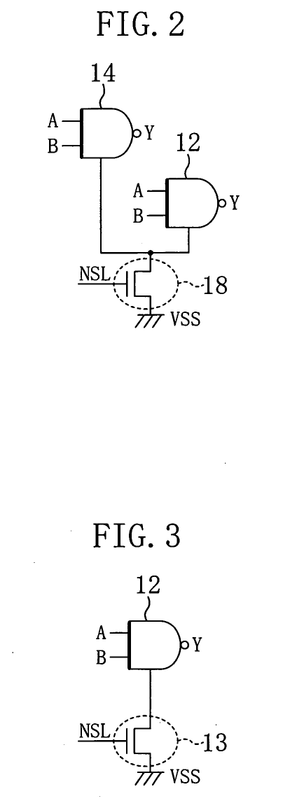

FIG. 2 is a gate level circuit diagram of the semiconductor integrated circuit of FIG. 1. FIG. 3 is a gate level circuit diagram of a 2-input NAND cell having a switch. The circuit of FIG. 2 includes 2-input NAND gates 12 and 14 (logic circuits) and a transistor 18 which functions as a switch (switch transistor). The circuit of FIG. 3 includes a 2-input NAND gate 12 and a switch transistor 13.

If two circuits of FIG. 3 adjoin each other and a same signal is supplied to the switch transistors 13 of these two circuits, an equivalent circuit can be realized by sharing one switch transistor 18 between the two circuits as shown in FIG. 2. Thus, the number of switch transistors is reduced, and as a result, the circuit area is reduced.

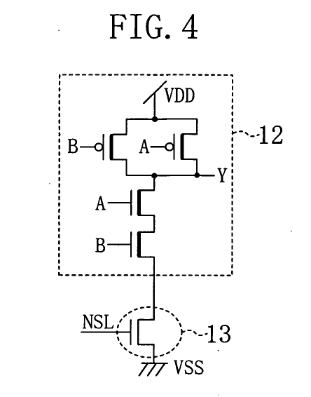

FIG. 4 is a transistor level circuit diagram of the 2-input NAND cell of FIG. 3. The 2-input NAND gate 12 is formed by transistors with low threshold voltage (Vt), and the switch transistor 13 is formed by a transistor with high threshold voltage (Vt). Every current path between the 2-input NAND gate 12 and power supply VSS goes through the switch transistor 13. The switch transistor 13 controls the supply of power to the 2-input NAND gate 12.

The switch transistor 13 is an NMOS transistor to which an inverted sleep signal NSL is input. When the inverted sleep signal NSL is at low level, the switch transistor 13 is off. Accordingly, the current path from the 2-input NAND gate 12 to power supply VSS is cut off, whereby the leakage current is cut off. Thus, the standard cell of FIG. 4 is controlled by the inverted sleep signal NSL as to whether or not the leakage current is cut off.

In FIG. 1, the first standard cell 120 includes a circuit which is equivalent to the combination of the 2-input NAND gate 12 and the switch transistor 18 of FIG. 2. The second standard cell 140 includes a circuit which is equivalent to the combination of the 2-input NAND gate 14 and the switch transistor 18 of FIG. 2.

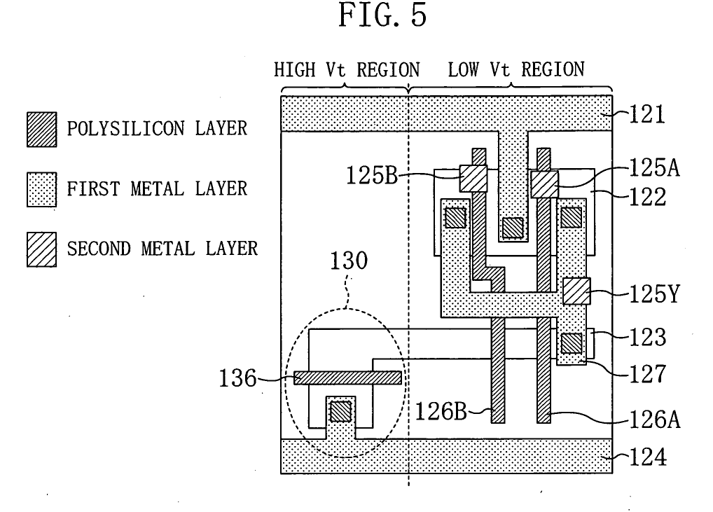

FIG. 5 is a cell layout showing an example of the structure of the 2-input NAND cell of FIG. 3. This cell is the 2-input NAND cell of the circuit of FIG. 3, and layout data of this cell are stored in a layout library as a standard cell.

The standard cell of FIG. 5 includes a VDD power supply wiring 121, a p-type diffusion region 122, an n-type diffusion region 123, a VSS power supply wiring 124, an input pin 125A for signal A, an input pin 125B for signal B, an output pin 125Y for signal Y, gate electrodes 126A and 126B, a wiring 127, and a switch transistor 130. The switch transistor 130 has a gate electrode 136. The gate electrode 136 of the switch transistor 130 includes a straight portion elongated in a direction perpendicular to the boundary lines at left and right sides of the standard cell. The gate electrode 136 is elongated in a direction perpendicular to the gate electrodes 126A and 126B of the transistors of the 2-input NAND gate.

The VDD power supply wiring 121, the VSS power supply wiring 124, and the wiring 127 are in a first metal layer. The input pin 125A for signal A, the input pin 125B for signal B, the output pin 125Y for signal Y are in a second metal layer. The gate electrodes 126A, 126B, and 136 are in a polysilicon layer.

The standard cell of FIG. 5 includes a region in which transistors with low threshold voltage are formed (low Vt region) and a region in which a transistor with high threshold voltage is formed (high Vt region). In the low Vt region, the transistors of the 2-input NAND gate 12 of FIG. 3 are formed. In the high Vt region, the switch transistor 130 (transistor 13 of FIG. 3) is formed.

If two cells of the 2-input NAND cell of FIG. 5 adjoin each other side by side, the cell layout of FIG. 5 and a horizontally flipped cell layout of FIG. 5 are placed such that one of the high Vt regions overlaps the other. And the two transistors 130 of the high Vt regions are replaced by one switch transistor 180. Further, an input pin 185 is provided on a gate electrode 186 of the transistor 180. The gate electrode 186 of the transistor 180 is elongated in a direction perpendicular to the boundary line between the standard cell 120 and the standard cell 140.

In FIG. 1, a VDD power supply wiring 161, n-type diffusion region 163, and a VSS power supply wiring 164 are consolidations of the VDD power supply wirings 121, the n-type diffusion regions 123, and the VSS power supply wirings 124 of the two standard cells, respectively. A p-type diffusion region 142, input pins 145A and 145B, an output pin 145Y, gate electrodes 146A and 146B, and a wiring 147 of the standard cell 140 correspond to the p-type diffusion region 122, the input pins 125A and 125B, the output pin 125Y, the gate electrodes 126A and 126B, and the wiring 127 of the standard cell 120, respectively.

Since the longitudinal direction of the gate electrode 136 of the switch transistor 130 is perpendicular to the left and right sides of the standard cell as shown in FIG. 5, the source region, the gate electrode, and the drain region of the switch transistor 130 are in the vicinity of the boundary line of the standard cells. Thus, the two standard cells 120 and 140 can share the switch transistor 180 as shown in FIG. 1. That is, the standard cells 120 and 140 can share the source region, the gate electrode, and the drain region of the switch transistor 180. As a result, the circuit area can be reduced as compared with a circuit where two cells of FIG. 5 are simply placed side by side.

The switch transistor 180 of FIG. 1 and the switch transistor 130 of FIG. 5 are formed in the high Vt region and therefore have a high threshold voltage as compared with the other transistors of the first and second standard cells 120 and 140 (which are formed in the low Vt region).

In the case where two NAND gates 12 and 14 share the switch transistor 18 as shown in FIG. 2, i.e., in the case where two standard cells 120 and 140 share the switch transistor 180 as shown in FIG. 1, one switch transistor 180 needs to supply the current to two 2-input NAND gates. The current supplied to each of the 2-input NAND gate may be decreased as compared with a case where the switch transistor is not shared. The current decrease can cause a decrease in operation speed.

In view of such, the gate width of the switch transistors 130 and 180 is greater than that of the other transistors as shown in FIG. 1 and FIG. 5. With this, the decrease in operation speed due to the current decrease is suppressed.

Although in the above-described example of embodiment 1 a switch is shared between 2-input NAND cells, a switch can be shared in the same way even between standard cells of another logic or between standard cells of different logics. That is, a switch can be shared between any standard cells which have switch transistors where the same potential is supplied to the source regions and the same signal is supplied to the gate electrodes, and as a result, the same effects can be achieved.

### EMBODIMENT 2

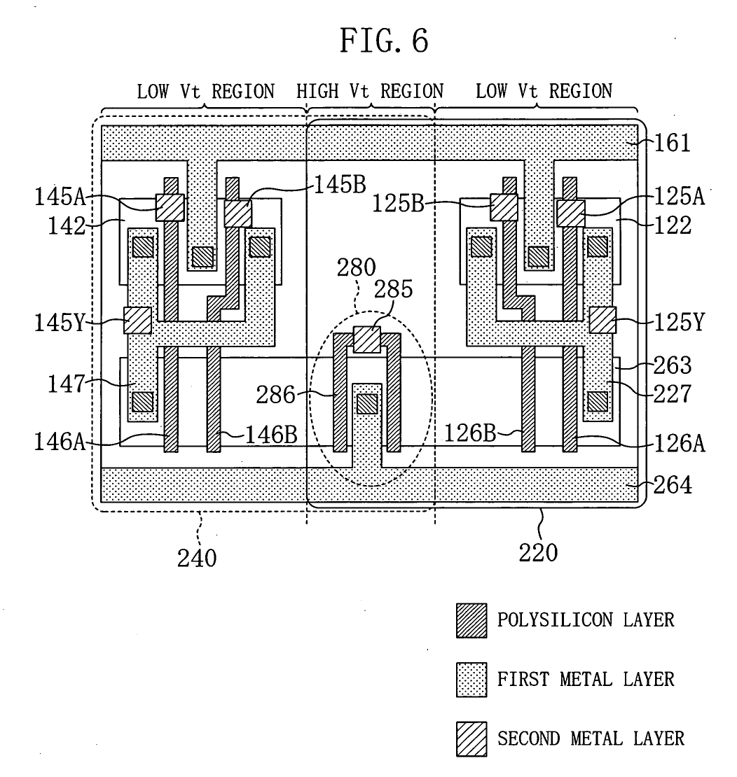

FIG. 6 is a layout of a semiconductor integrated circuit according to embodiment 2 of the present invention. The semiconductor integrated circuit of FIG. 6 includes a first standard cell 220 and a second standard cell 240. Part of the first standard cell 220 is shared with the second standard cell 240. Hereinafter, a method for designing the layout of the semiconductor integrated circuit of FIG. 6 is described.

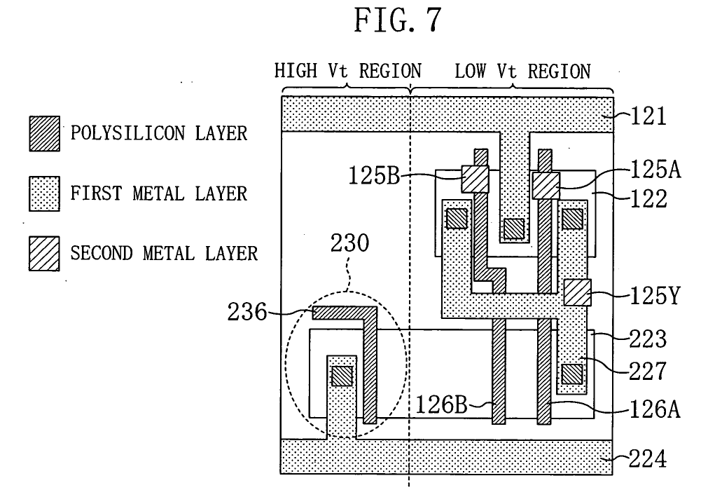

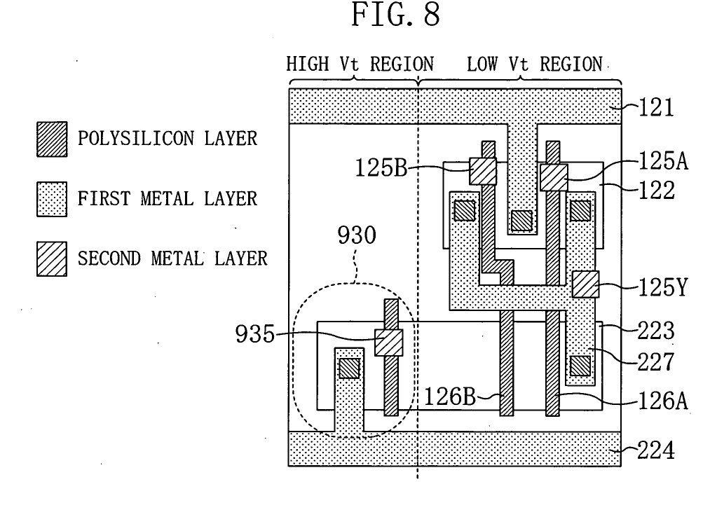

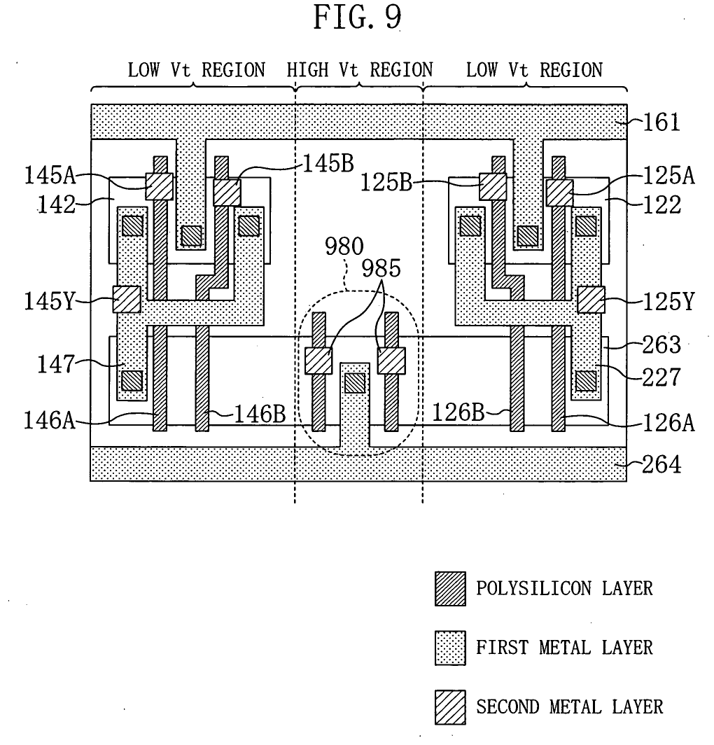

FIG. 7 is a cell layout showing another example of the structure of the 2-input NAND cell of FIG. 3. This cell is the 2-input NAND cell of the circuit of FIG. 3, and the layout data of this cell is stored in a layout library as a standard cell. The standard cell of FIG. 7 has substantially the same structure as that of the standard cell of FIG. 5 except that the shapes of an n-type diffusion region 223, a VSS power supply wiring 224, a wiring 227, and a gate electrode 236 are different.

As shown in FIG. 7, the gate electrode 236 of the switch transistor 230 includes a straight portion which is elongated in a direction perpendicular to the boundary line between the standard cell 220 and the standard cell 240, in other words, a straight portion which is elongated in a direction perpendicular to the boundary lines at left and right sides of the standard cells 220 and 240. The standard cell of FIG. 7 has an input pin 125A for signal A, an input pin 125B for signal B, and an output pin 125Y for signal Y but does not have an input pin for supplying an inverted sleep signal NSL to the gate electrode 236 of the switch transistor 230.

The layout of the semiconductor integrated circuit is designed as described below. In the case where standard cells each having a switch as shown in FIG. 7 are placed side by side and the source regions of switch transistors of the adjacent standard cells have the same potential and the same signal is input to the gate electrodes of the adjacent standard cells, the source regions and the gate electrodes of the switch transistors are consolidated to be shared between the adjacent two standard cells.

Then, an input pin 285 for the inverted sleep signal NSL is provided on the gate electrode of the switch transistor shared between the standard cells.

Thus, the layout of the semiconductor integrated circuit has been designed as shown in FIG. 6. In the semiconductor integrated circuit of FIG. 6, the first standard cell 220 includes a cell layout of FIG. 7, and the second standard cell 240 includes a horizontally flipped cell layout of FIG. 7.

In the semiconductor integrated circuit of FIG. 6, the first standard cell 220 and the second standard cell 240 share the source region and the gate electrode 286 of the switch transistor 280 which functions as the first and second transistors. Therefore, the circuit area is reduced as compared with a circuit where two standard cells of FIG. 7 are simply placed side by side. Further, the number of input pins for the inverted sleep signal is reduced to one, therefore, increase of wiring resources and reduction of routing congestion are achieved. As a result, the circuit area can be reduced.

As described above, sharing of the gate electrode is easily achieved by preparing a standard cell where part of the gate electrode of the switch transistor 230 is elongated in a direction perpendicular to the boundary line between standard cells placed side by side.

In a design method of a semiconductor integrated circuit based on a standard cell scheme, a delay library which has a delay value of a standard cell is prepared, and a delay calculation of the designed semiconductor integrated circuit is carried out using this delay library. In the semiconductor integrated circuit of FIG. 6, the number of gates to which a current is supplied from one VSS power supply wiring is two, whereas it is one in the standard cell of FIG. 7. Therefore, the current supplied to each of the 2-input NAND gate is decreased as compared with a case where the switch transistor is not shared. The current decrease can cause a decrease in operation speed.

In other words, in the semiconductor integrated circuit of FIG. 6, the on-current which flows through each 2-input NAND gate is decreased as compared with the standard cell of FIG. 7. As a result, an error is caused between an actual delay value of a standard cell and the delay value in the delay library.

In view of such a problem, another delay library for storing a delay value of a 2-input NAND cell whose switch is shared as shown in FIG. 6 is prepared in advance in addition to the delay library for storing a delay value of the cell without switch sharing. One of these delay libraries is selected for a delay calculation. In the case where a switch is shared between two standard cells, the delay library of the switch-shared 2-input NAND cell is used for delay calculation in place of the delay library of the standard cell, whereby the error caused between an actual delay value and the delay value of the delay library can be decreased.

In the above-described example of embodiment 2, before switch transistors of two standard cells are consolidated, an input pin is not provided to the switch transistors, i.e., an input pin is provided after the consolidation. Alternatively, according to the present invention, it is possible that input pins are provided to switch transistors before consolidation, and one of the two input pins provided on the gate electrode of the consolidated switch transistor is deleted. Also in this case, the circuit area can be reduced.

In the above-described example of embodiment 2, the method for designing the layout of the semiconductor integrated circuit of FIG. 6 using the standard cell of FIG. 7 has been described. In the same manner, the layout of the semiconductor integrated circuit of FIG. 1 can be designed using the standard cell of FIG. 5.

In the above embodiments, a layout design method wherein switches of adjacently-placed standard cells are consolidated has been described. However, alternatively, it is possible that layout data of a switch-shared 2-input NAND cell (complex cell) as shown in FIG. 1 or FIG. 6 is prepared in a layout library, and adjacently-placed standard cells having switches are replaced by the complex cell.

In the above-described embodiments, an n-type transistor is used as a switch transistor. However, alternatively, a p-type transistor may be used as a switch transistor according to the circuit of the standard cell.

In the above embodiments, sharing of a switch transistor between standard cells having switches has been described. However, it is apparent to those skilled in the art that sharing of a transistor different from the switch transistor is also possible in any semiconductor integrated circuit having two cells between which the gate electrode and the source region can be shared.

As described above, the present invention can reduce the area of a semiconductor integrated circuit and is therefore useful for a standard-cell based semiconductor integrated circuit which is demanded to achieve high speed operation, low power consumption, and small circuit area.

What is claimed is:

1. A semiconductor integrated circuit, comprising:
a first standard cell which includes a first logic circuit and a first switch for controlling current supply to the first logic circuit; and
a second standard cell which includes a second logic circuit and a second switch for controlling current supply to the second logic circuit,
wherein the first switch is shared with the second standard cell as the second switch.

2. The semiconductor integrated circuit of claim 1, wherein the first switch exists on a side which is closer to the second logic circuit.

3. The semiconductor integrated circuit of claim 1, wherein the first switch is a transistor.

4. The semiconductor integrated circuit of claim 3, wherein the gate width of the transistor which constitutes the first switch is greater than those of the other transistors included in the first and second standard cells.

5. The semiconductor integrated circuit of claim 3, wherein a source region of the transistor which constitutes the first switch is shared with a transistor which functions as the second switch.

6. The semiconductor integrated circuit of claim 3, wherein a gate electrode of the transistor which constitutes the first switch is shared with a transistor which functions as the second switch.

7. The semiconductor integrated circuit of claim 3, wherein a gate electrode of the transistor which constitutes the first switch includes a straight portion which is elongated in a direction perpendicular to a boundary line between the first standard cell and the second standard cell.

8. The semiconductor integrated circuit of claim 3, wherein a drain region of the transistor which constitutes the first switch is shared with a transistor which functions as the second switch.

9. The semiconductor integrated circuit of claim 3, wherein a threshold voltage of the transistor which constitutes the first switch is higher than those of the other transistors included in the first and second standard cells.

10. A semiconductor integrated circuit, comprising:
a first standard cell which includes a first logic circuit and a first transistor for controlling current supply to the first logic circuit; and
a second standard cell which includes a second logic circuit and a second transistor for controlling current supply to the second logic circuit,
wherein a source region of the first transistor is shared with the second standard cell as a source region of the second transistor, and
a gate electrode of the first transistor is shared with the second standard cell as a gate electrode of the second transistor.

11. The semiconductor integrated circuit of claim 10, wherein a gate electrode of the first transistor includes a straight portion which is elongated in a direction perpendicular to a boundary line between the first standard cell and the second standard cell.

12. The semiconductor integrated circuit of claim 10, wherein a threshold voltage of the first transistor is higher than those of the other transistors included in the first and second standard cells.

13. A standard cell, comprising:
a logic circuit; and
a control transistor for controlling current supply to the logic circuit,
wherein a gate electrode of the control transistor includes a straight portion which is elongated in a direction perpendicular to gate electrodes of transistors which constitute the logic circuit.

14. The standard cell of claim 13, wherein the gate electrode of the control transistor includes only the straight portion which is elongated in a direction perpendicular to the gate electrodes of the transistors which constitute the logic circuit.

15. A method for designing a layout of a semiconductor integrated circuit, comprising the steps of:
placing a first standard cell which includes a first logic circuit and a first switch for controlling current supply to the first logic circuit and a second standard cell which includes a second logic circuit and a second switch for controlling current supply to the second logic circuit such that the first switch is shared with the second standard cell as the second switch while no pin is provided in a shared portion of the first and second standard cells; and
providing only one pin in the shared portion.

16. The method of claim 15, further comprising the step of selecting one of a delay library having a delay value which is to be caused when a switch is shared between the first and second standard cells and a delay library having a delay value which is to be caused when a switch is not shared between the first and second standard cells to perform a delay calculation using the selected delay library.

17. The method of claim 15, wherein the step of placing the standard cells includes replacing, if the first and second standard cells are placed side by side, the first and second standard cells with a complex cell using a layout library which includes layout data of the first and second standard cells and layout data of the complex cell, the complex cell being constructed by consolidating the first and second standard cells by sharing the switch therebetween.

18. A method for designing a layout of a semiconductor integrated circuit, comprising the steps of:
placing a first standard cell which includes a first logic circuit and a first switch for controlling current supply to the first logic circuit and a second standard cell which includes a second logic circuit and a second switch for controlling current supply to the second logic circuit such that the first switch is shared with the second standard cell as the second switch while pins are provided in a shared portion of the first and second standard cells; and
deleting one of the pins provided in the shared portion.

19. The method of claim 18, further comprising the step of selecting one of a delay library having a delay value which is to be caused when a switch is shared between the first and second standard cells and a delay library having a delay value which is to be caused when a switch is not shared between the first and second standard cells to perform a delay calculation using the selected delay library.

20. The method of claim 18, wherein the step of placing the standard cells includes replacing, if the first and second standard cells are placed side by side, the first and second standard cells with a complex cell using a layout library which includes layout data of the first and second standard cells and layout data of the complex cell, the complex cell being constructed by consolidating the first and second standard cells by sharing the switch therebetween.

21. A method for designing a layout of a semiconductor integrated circuit, comprising the steps of:
placing a first standard cell which includes a first logic circuit and a first transistor for controlling current supply to the first logic circuit and a second standard cell which includes a second logic circuit and a second transistor for controlling current supply to the second logic circuit such that a source region of the first transistor is shared with the second standard cell as a source region of the second transistor, and a gate electrode of the first transistor is shared with the second standard cell as a gate electrode of the second transistor, while no pin is provided in a shared portion of the first and second standard cells; and
providing only one pin in the shared portion.

22. The method of claim 21, further comprising the step of selecting one of a delay library having a delay value which is to be caused when a transistor is shared between the first and second standard cells and a delay library having a delay value which is to be caused when a transistor is not shared between the first and second standard cells to perform a delay calculation using the selected delay library.

23. The method of claim 21, wherein the step of placing the standard cells includes replacing, if the first and second standard cells are placed side by side, the first and second standard cells with a complex cell using a layout library which includes layout data of the first and second standard cells and layout data of the complex cell, the complex cell being constructed by consolidating the first and second standard cells by sharing the transistor therebetween.

24. A method for designing a layout of a semiconductor integrated circuit, comprising the steps of:
placing a first standard cell which includes a first logic circuit and a first transistor for controlling current supply to the first logic circuit and a second standard cell which includes a second logic circuit and a second transistor for controlling current supply to the second logic circuit such that a source region of the first transistor is shared with the second standard cell as a source region of the second transistor, and a gate electrode of the first transistor is shared with the second standard cell as a gate electrode of the second transistor, while pins are provided in a shared portion of the first and second standard cells; and
deleting one of the pins provided in the shared portion.

25. The method of claim 24, further comprising the step of selecting one of a delay library having a delay value which is to be caused when a transistor is shared between the first and second standard cells and a delay library having a delay value which is to be caused when a transistor is not shared between the first and second standard cells to perform a delay calculation using the selected delay library.

26. The method of claim 24, wherein the step of placing the standard cells includes replacing, if the first and second standard cells are placed side by side, the first and second standard cells with a complex cell using a layout library which includes layout data of the first and second standard cells and layout data of the complex cell, the complex cell being constructed by consolidating the first and second standard cells by sharing the transistor therebetween.
